(19) United States
(12) Patent Application Publication
(10) Pub. No.: US 2026/0338888 A1
(43) Pub. Date: Oct. 29, 2026

(54) SINGLE LINE RADIOFREQUENCY COIL ELEMENT SYSTEM

(71) Applicant: Canon Kabushiki Kaisha, Tokyo (JP)

(72) Inventors: David OTTO BRUNNER, Jona (CH); Yoshinori HAMAMURA, Vernon Hills, IL (US)

(73) Assignee: Canon Kabushiki Kaisha, Tokyo (JP)

(21) Appl. No.: 19/189,350

(22) Filed: Apr. 25, 2025

(51) Int. Cl. G01R 33/36; G01R 19/165

(52) U.S. Cl. CPC G01R 33/3642; G01R 19/16571

(57) ABSTRACT

An apparatus for decoupling magnetic resonance imaging (MRI) coils, including an amplifier configured to amplify a radiofrequency (RF) signal received from an RF coil of an MRI scanner; state detection circuitry configured to output a control signal based on a state of the RF coil; a unipolar diode driver configured to receive the control signal and output a bias voltage based on the received control signal; a voltage regulator configured to output an amplifier bias voltage to the amplifier; and a transmission line configured to transmit the amplified RF signal from the amplifier, the control signal to the unipolar diode driver, and a bias voltage supply, wherein the outputted amplifier bias voltage from the voltage regulator is applied to the amplifier and the outputted bias voltage from the unipolar diode driver is applied to a detuning switch of the RF coil that is connected to the amplifier.

### BACKGROUND

### Field

The present disclosure is related to tuning and detuning of radiofrequency (RF) coils in magnetic resonance imaging (MRI) systems.

### Description of Related Art

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Tuning and detuning of radiofrequency (RF) receiver coils of a magnetic resonance imaging (MRI) system can prevent interference or damage to the receiver coils while the MRI system is in a transmission state. The tuning/detuning mechanism can include circuitry coupled to the receiver coils that can be controlled based on the state of the MRI system.

### SUMMARY

In one embodiment, the present disclosure is directed to an apparatus for decoupling magnetic resonance imaging (MRI) coils, comprising an amplifier configured to amplify a radiofrequency (RF) signal received from an RF coil of an MRI scanner; state detection circuitry configured to output a control signal based on a state of the RF coil; a unipolar diode driver configured to receive the control signal and output a bias voltage based on the received control signal; a voltage regulator configured to output an amplifier bias voltage to the amplifier; and a transmission line configured to transmit the amplified RF signal from the amplifier, the control signal to the unipolar diode driver, and a bias voltage supply, wherein the outputted amplifier bias voltage from the voltage regulator is applied to the amplifier and the outputted bias voltage from the unipolar diode driver is applied to a detuning switch of the RF coil that is connected to the amplifier, and the amplifier, the state detection circuitry, the unipolar diode driver, and the voltage regulator are on a first end of the transmission line.

In one embodiment, the present disclosure is directed to an apparatus for decoupling magnetic resonance imaging (MRI) coils, comprising an amplifier configured to amplify a radiofrequency (RF) signal received from an RF coil of an MRI scanner; a unipolar diode driver configured to receive a control signal and output a bias voltage based on the received control signal; a voltage regulator configured to output an amplifier bias voltage to the amplifier; and a transmission line configured to transmit the amplified RF signal from the amplifier, the control signal to the unipolar diode driver, and a bias voltage supply, wherein the outputted amplifier bias voltage from the voltage regulator is applied to the amplifier and the outputted bias voltage from the unipolar diode driver is applied to a detuning switch of the RF coil that is connected to the amplifier, and the amplifier, the unipolar diode driver, and the voltage regulator are on a first end of the transmission line.

In one embodiment, the present disclosure is directed to a method of decoupling magnetic resonance imaging (MRI) coils, comprising determining a state of a radiofrequency (RF) coil of an MRI scanner; generating a control signal based on the determined state of the RF coil; transmitting the generated control signal to a unipolar diode driver; outputting a stabilized amplifier bias voltage from a voltage regulator to an amplifier configured to amplify an RF signal received from the RF coil; outputting a bias voltage from the unipolar diode driver based on the generated control signal; and applying the outputted stabilized amplifier bias voltage from the voltage regulator to the amplifier and the outputted bias voltage from the unipolar diode driver to a detuning switch of the RF coil that is connected to the amplifier, wherein the detuning switch of the RF coil is a PIN diode coupled to a parallel LC circuit, and the amplified RF signal, the control signal, and a bias voltage supply are transmitted by a single transmission line.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic of a detuning mechanism, according to one embodiment of the present disclosure;

FIG. 2 is a schematic of a diode driver of a detuning mechanism, according to one embodiment of the present disclosure;

FIG. 3 is a schematic of a diode driver of a detuning mechanism, according to one embodiment of the present disclosure;

FIG. 4 is a schematic of control of a detuning mechanism, according to one embodiment of the present disclosure;

FIG. 5 is a schematic of a detuning mechanism, according to one embodiment of the present disclosure;

FIG. 6 is a schematic of a detuning mechanism, according to one embodiment of the present disclosure; and

FIG. 7 is a schematic block diagram of a magnetic resonance imaging system, according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For example, the order of discussion of the different steps as described herein has been presented for clarity’s sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Furthermore, as used herein, the words “a,” “an,” and the like generally carry a meaning of “one or more,” unless stated otherwise.

A magnetic resonance imaging (MRI) system can include one or more radiofrequency (RF) coils configured to transmit and/or receive energy. An MRI system can alternate between a transmission state and a receiving state during operation. The transmission state can refer to a period when an RF coil is transmitting RF energy to excite atoms in an imaging object. The transmitted RF energy can be, for example, a pulse. The receive state can refer to a period when an RF coil is receiving RF energy, e.g., from the imaging object in response to the transmitted RF energy. The energy of a transmitted RF pulse is typically many orders of magnitude greater than the energy that is received during the receive state. A receiver coil can be detuned during the transmission state in order to be decoupled from transmission coils and to prevent interference or damage to the receiver coil circuitry from the transmission of an RF pulse. Detuning an RF coil can reduce the current flowing through the RF coil.

A receiver coil can include one or more receiver channels for receiving and processing signals from the receiver coil. Each receiver channel can be coupled to a length of the receiver coil. A receiver channel can include at least a detuning mechanism and an amplifier for amplifying the RF signals received from a length of the receiver coil. A received RF signal can have an amplitude in the millivolts. Therefore, it is important to maximize signal-to-noise ratio (SNR) in amplifying and transmitting received RF signals. The amplifier can be referred to as a preamplifier. In one embodiment, the amplifier can be a low noise amplifier (LNA). The detuning mechanism of the receiver channel can receive a control signal to trigger the detuning of the length of the receiver coil during the transmission state. The control signal can also trigger tuning of the length of the receiver coil during the receiving state so that the amplifier can amplify received RF signals.

Each connection in the receiver channel and/or coil can require extensive shielding and cabling to ensure that the circuit elements function properly and without interference. For example, the receiver channel can include balancing units (baluns); RF cabling connections to the coil, ground, driving electronics, etc.; and RF shielding. RF transmission cabling (e.g., coaxial lines or differential lines) can take up a large amount of space and can be limited in how much the cabling can be bent or compressed. Reduction of cabling in a receiver channel by moving components closer together and sharing transmission lines can reduce the footprint of the receiver channel. Reducing the footprint of the receiver channel can enable an increase in the number of receiver channels connected to a receiver coil, which can improve signal-to-noise ratio (SNR) and parallel imaging performance. Reduction of cabling and a decrease in coil size can also reduce the cost of goods in an MRI system and make the MRI system safer, more accurate, and more comfortable for patients.

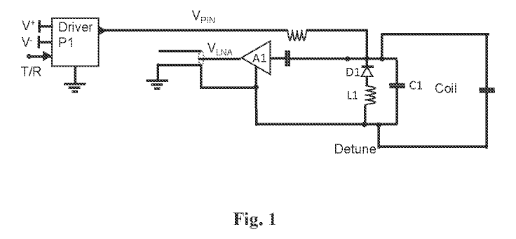

FIG. 1 is an example of a detuning circuit. The detuning circuit can include a parallel LC circuit having an inductor L1 and capacitor C1 in parallel. The LC circuit can be connected to the receiver coil in series. The impedance of the LC circuit can be modified via a tuning switch in series with one of the LC components (inductor L1 or capacitor C1). In one embodiment, the switch can be a diode, e.g., a PIN diode D1 in series with the inductor L1. When the diode D1 is forward biased, the LC circuit inserts a high impedance in series with the receiver coil to detune the receiver coil. When the diode D1 is reverse biased, the detuning mechanism is deactivated and current can flow through the coil and to the preamplifier in series with the LC circuit. In this manner, the diode D1 acts as a switch that tunes and detunes the receiver coil. In one embodiment, the diode can be biased by applying a bias voltage (signal) to the diode via a PIN diode driver P1. The detuning circuit is connected to the input of the preamplifier A1 (e.g., an LNA) so that the current from the receiver coil can flow to the preamplifier A1 during the receiving state. The output of the preamplifier A1 can be transmitted via a transmission cable to an MRI data processor for digital conversion and processing.

The diode bias voltage V_{PIN} can be delivered by a diode driver P1. In a typical MRI system, the diode driver can be a bipolar voltage supply having a single output applied to a terminal of the diode D1, e.g., the cathode of the diode D1 as illustrated in FIG. 1. The diode driver P1 can provide a first voltage (e.g., negative voltage V⁻) to forward bias the diode D1 or a second voltage (e.g., positive voltage V⁺) to reverse bias the diode D1. The polarity of the first voltage and second voltage can depend on the terminal to which the voltage from the diode driver P1 is applied. The diode driver P1 can be controlled by a control signal (T/R signal). The control signal can indicate whether the MRI system is in a transmission (T) state or a receiving (R) state. The diode bias voltage V_{PIN} can be set as a positive or negative voltage based on the control signal and the orientation of the diode D1. As the magnitude of transmitted RF pulses increases, the magnitude of the forward bias current supplied to the diode D1 can increase to ensure that the receiver coil is properly detuned. When the diode driver is provided at a distance (remotely) from the detuning circuit, cabling is required to carry the diode bias voltage to the diode and a bipolar supply is preferred to reduce cabling needed for current return paths while properly biasing the diode. In one embodiment, the voltage V_{PIN} from the diode driver P1 can be delivered through one or more chokes (e.g., inductors) to filter out high-frequency components of the voltage signal, as illustrated in FIG. 1.

In the circuit of FIG. 1, the diode driver P1 only drives the diode D1 of the detuning circuit. The preamplifier A1 of the receiver channel is driven and biased by a separate positive voltage supply (not illustrated). Driving the preamplifier with a switching (varying, unstable) voltage (e.g., with an inverting supply) can cause a transient signal and gain behavior in the preamplifier, resulting in inaccurate MRI readings. As a result, a separate voltage supply from the bipolar diode driver P1 of FIG. 1 is needed to bias the preamplifier. The receiver coil therefore requires at least three separate connections and transmission lines to carry the diode bias voltage, the preamplifier bias voltage, and a ground/current return line.

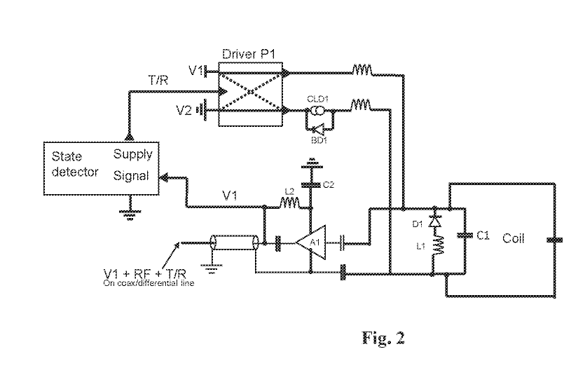

In one embodiment, the present disclosure is directed to a receiver coil design including a detuning mechanism and a preamplifier driven by a shared unipolar source. FIG. 2 is an example of a receiver coil design according to one embodiment. In one embodiment, the diode driver P1 can include a commutator switch configured to reverse a polarity of a direct current (DC) voltage applied to the detuning mechanism. In one embodiment, the diode driver P1 can include one or more switches. For example, the diode driver P1 illustrated in FIG. 2 can be a double-pole double-throw (DPDT) switch. The pole of each switch can be connected to a bias voltage supply of the diode driver P1. The bias voltage supply can include, for example, a first voltage V1 or a second voltage V2. In one embodiment, the diode driver P1 can be a unipolar driver. In one embodiment, the first voltage V1 can be a positive voltage and the second voltage V2 can be ground (0V). In one embodiment, the first and the second voltage V1, V2 can both be positive voltages. The difference between the first voltage V1 and the second voltage V2 can be at least a required biasing voltage of the diode D1 of the detuning mechanism. In one embodiment, the receiver coil of FIG. 2 can include a voltage regulator.

As illustrated in FIG. 2, a first pole of the DPDT switch P1 can be connected to the cathode of the diode D1 and a second pole of the DPDT switch P1 can be connected to the anode of the diode D1. In this manner, the voltage across the diode D1 can be controlled via the DPDT switch P1 to ensure that the diode is fully forward or reverse biased. For example, when the first pole is connected to a positive voltage V1 and the second pole is connected to ground, the diode D1 can be reverse biased. When the first pole is connected to ground and the second pole is connected to the positive voltage V1, the diode D1 can be forward biased. The pole positions of the DPDT switch can be set based on a control signal (T/R signal). The control signal can trigger a switch in the positions of both poles in the DPDT switch. In this manner, the DPDT switch P1 can provide a positive voltage and a ground connection sufficient for biasing the diode D1 using a single control signal input. In one embodiment, the detuning mechanism can include more than one diode connected in series. The first voltage can be applied to an anode of a first diode in the series of diodes and the second voltage can be applied to a cathode of a last diode in the series of diodes. The first voltage and second voltage can thereby bias the series of diodes to tune the receiver coil.

It can be appreciated that the PIN diode D1 is provided herein as a non-limiting example of a tuning switch of the detuning circuit. Switching elements can include, but are not limited to, transistors, phototransistors, mechanical switches (e.g., micro-electro-mechanical system (MEMS) switches), etc. The driver P1 described herein can be used to drive any switching element. For example, the driver P1 can output a gate voltage applied to a transistor as a switching element. The gate voltage output by the driver P1 can be set by a control signal inputted to the driver P1.

In one embodiment, the detuning mechanism can include a current limiting element, e.g., one or more current limiting diodes. In one embodiment, the current limiting element can include a current limiting diode and a feedback diode BD1 across a current source to the detuning circuit. The feedback diode represents a mean to bypass a current spike around the current source when the bias of the PIN diode D1 is switched from forward to reverse bias in order to switch the coil from transmit to receive mode.

In one embodiment, the control signal can be supplied by a state detection module (e.g., circuitry). The state detection module can determine whether the MRI system is in the transmission state or the receiving state and can generate a corresponding control signal as an input to the DPDT switch. In one embodiment, the state detection circuitry can generate the control signal based on sensors associated with the MRI scanner. For example, the sensors can determine the state (transmission state, receiving state) of the MRI scanner. As an example, the control signal can be an RF signal, a voltage pulse, or a level shift of a voltage at the T/R input pin of the diode driver P1. The control signal can trigger the DPDT switch P1 to switch the position of each output. In one embodiment, the state detection circuitry can further be powered by a voltage, e.g., the first voltage V1 that is supplied to and output by the DPDT switch P1.

Because the diode driver P1 of the present disclosure is a unipolar voltage source, the diode driver P1 can also provide a biasing supply to the preamplifier A1. For instance, the voltage at the anode of the diode D1 can charge a capacitor tied to the supply of the preamplifier A1, as illustrated in FIG. 2. The preamplifier A1 can then be biased with the voltage V1 output by the driver P1. When the driver P1 is a unipolar voltage source, there is no risk of inverting the preamplifier A1.

In one embodiment, the receiver coil of FIG. 2 can use a single transmission line (e.g., coaxial line, differential line) to transmit the bias voltage supply for the diode D1 of the detuning mechanism as well as the preamplifier A1. The transmission line can transmit the first voltage V1 of the DPDT and the second voltage V2 (e.g., supplying a ground). In one embodiment, the transmission line can further transmit the control signal to the diode driver. In one embodiment, the receiver coil design can include a low-pass filter such as an LC circuit at the supply of the preamplifier A1 illustrated in FIG. 2. The inductor L2 and capacitor L2 of the filter can remove the control signal from the supply node of the preamplifier to supply the pure bias voltage (e.g., the first voltage of the DPDT switch). In this manner, a single transmission line connected to the preamplifier can carry voltage signals to control and supply power to multiple components of the receiver coil. In one embodiment, the same transmission line can also transmit an amplified RF signal from the preamplifier A1 for further MRI processing. This embodiment can thereby significantly reduce the amount of cabling required for a receiver channel and coil and enable combining signals on a single transmission line. In this embodiment, the diode driver can also be located in physical proximity to the pre-amplifier without interference or transient behavior.

In one embodiment, the receiver coil can include one or more current-limiting elements. Current-limiting elements can include, but are not limited to, resistors, transistors, capacitors, diodes, etc. For example, an output of the diode driver P1 can be connected to a current-limiting diode CLD. In one embodiment, the current-limiting diode CLD can be bypassed by a bypass diode BD1 to provide a reverse bias to the diode D1 as needed. In one embodiment, the receiver coil can include an active current source configured to inject a current into an element. For example, an active current source can inject a current to stabilize the preamplifier. In one embodiment, a current-limiting element or current source in the receiver coil can be capacitively bypassed to charge the diode capacitance for reverse bias.

It can be appreciated that the diode driver P1 can be implemented via a number of switching mechanisms, including, but not limited to, transistor-based switches, electromechanical switches, electro-optical elements (e.g., optocoupler, optical transistor), etc. In one embodiment, the control signal can include an optical signal. In one embodiment, the diode driver can include an H-bridge. The voltage across the load of an H-bridge (e.g., the diode D1) can be controlled by selectively driving the switching components in the H-bridge using the control signal. The switching components can include, for example, transistors or relays. As an example, the control signal can drive the gates of transistors in an H-bridge to control the polarity of voltage across the diode D1. In one embodiment, an H-bridge can include elements configured to prevent a short circuit across the load, such as a bootstrapping diode and capacitor across one set of transistors in the H-bridge. In one embodiment, H-bridge circuitry can be integrated into a chip (IC). In one embodiment, the diode driver can include a differential operational amplifier, wherein the input to the differential operational amplifier is the control signal and the output of the differential operational amplifier is a first voltage V1. As an example, the first voltage V1 can be provided as a rail (supply) to the differential operational amplifier.

In one embodiment, the control signal can be a digital signal, wherein the voltage of the control signal alternates between a HIGH voltage and a LOW voltage (e.g., 0V). For example, the control signal can include a pulse train and the diode driver can be a pulse detector. In one example, the diode driver can include comparator circuitry or similar elements (e.g., Schmitt trigger) for comparing the control signal to a control threshold. The diode driver can output the first voltage or the second voltage for each switch based on the output of the comparator circuitry. In one embodiment, the diode driver can include a filtering circuit or voltage regulator to stabilize the control signal and prevent leakage of energy.

In one embodiment, a voltage (e.g., the first voltage V1) of the diode driver can be generated via a capacitive (e.g., charge pump) or inductive (e.g., buck/boost converter) switched-mode power supply. The switching element can be rapidly switched to generate the first voltage V1. The voltage driving the receiver coil can be greater than a minimum voltage that is needed to bias a diode of the detuning mechanism. Converting the driver voltage to a first voltage V1 via a switched-mode power supply can reduce losses in other elements of the receiver coil. The first voltage can then be applied to the diode of the detuning mechanism via a switch, H-bridge, etc. In one embodiment, the control signal can include the switching signals to the power supply. In one embodiment, the switching can be regulated to a constant forward current or voltage in order to mitigate biasing drifts of the circuitry, e.g., drifts resulting from temperature changes. The noise generated by the switch mode regulation can be minor or irrelevant compared to the transmission of high-power RF pulses during operation of the MRI.

In one embodiment, the control signal can trigger the diode driver via a pulse. For example, the control signal can include a pulse when the MRI system changes state. The pulse can be generated by the state detection circuitry based on sensor data or a state signal received by the state detection circuitry. In one embodiment, the control signal can include a pulse train, e.g., a PWM signal. In one embodiment, the diode driver can include or be coupled to a corresponding pulse or edge detection circuitry for receiving the pulsed control signal. For example, the diode driver can include circuitry to decode a PWM signal, calculate a root-mean-squared (RMS) of a signal, or decode log functions. In one embodiment, the diode driver can include comparator circuitry and can compare the control signal to a threshold. The diode driver can then output voltages based on the comparison between the control signal and the threshold.

In one embodiment, the diode driver can include a monostable circuit. The monostable circuit can have a default stable state (e.g., LOW output) and can be triggered by an input pulse to transition to an unstable state (e.g., HIGH output) for a predetermined period of time. The output then transitions back to the stable state after the predetermined period of time. The behavior of the timer circuit monostable circuit, including the length of the unstable state, can be configured via circuitry in connection with the monostable circuit. As an example, the length of the unstable state can be set as the length of a transmission or receiving state of the MRI system. The transition of the diode driver between two states can then be controlled by a single pulse train to the monostable circuit of the diode driver.

In one embodiment, the diode driver can include a latching circuit such as a flip-flop (e.g., T flip-flop). The output of the latching circuit can be controlled by an input pulse in the control signal. Each pulse input to the latching circuit can cause the output of the latching circuit to alternate (flip-flop) between a first state (e.g., HIGH state corresponding to a first voltage) and a second state (e.g., LOW state corresponding to a second voltage). The latching circuit then holds the new output until another pulse input is received. In this manner, the diode driver can be controlled using a pulse train as a control signal rather than a sustained voltage signal.

In one embodiment, the control signal can be superimposed on the transmission line connected to the diode driver. For example, the superimposed control signal can be a pulse or an RF signal (e.g., a signal that is on during the transmission stage). In one embodiment, the control signal can be transmitted directly via a transmitter antenna from the transmission circuitry of the MRI system. In one embodiment, the control signal can be an RF signal injected via a transmission line and/or coupled into the receiver coil from the transmission coil. For example, the output of the transmission coil or a separate pick-up circuit located in proximity to the transmission coil can be used to generate a control signal. A pick-up circuit can control the tuning of the coil without requiring a separate signal output from the transmission coil. The pick-up circuit can be useful for wireless signaling and operation of the receiver coil or when wired connections in the receiver coil fail. In one embodiment, the receiver coil can be battery driven.

In one embodiment, the diode driver can include three discrete output states. The output states can include a high-current forward bias voltage, a low-current bias voltage, and a reverse bias voltage (e.g., ground). In one embodiment, the control signal to the diode driver can be used to output one of the three output voltages. For example, the control signal can have three possible voltage levels, each voltage level corresponding to an output signal. In one embodiment, an active current source can generate the high current forward bias voltage and can stabilize the forward bias current. In one embodiment, the current of the voltage output can be set as a higher or lower current based on a number or type of elements that are being detuned. The use of a low-current bias voltage can result in power savings and improve the efficiency of the detuning mechanism. In one embodiment, the transmission line can transmit a control signal to the diode driver indicating one of the three output states to be output as the bias voltage. In one embodiment, the control signal can encode the one of the three output states via a pulse encoding scheme or a voltage level (e.g., one of three set voltage levels).

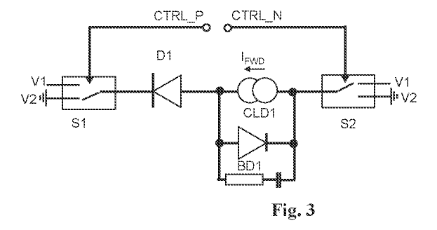

FIG. 3 is an illustration of a diode driver including a first SPDT switch S1 and a second SPDT switch S2 according to one embodiment. The terminals of each switch can include the first voltage V1 and the second voltage V2 (e.g., ground, as illustrated in FIG. 3). As an example, the first SPDT switch S1 can be connected to the cathode of the diode D1, and the second SPDT switch S2 can be connected to the anode of the diode D1. In a first state, the first SPDT switch S1 can be connected to the first voltage V1 and the second SPDT switch S2 can be connected to the second voltage V2 (e.g., ground) to apply a reverse bias to the diode D1. The first and second SPDT switches can be switched by the same control signal or by different control signals (CTRL_P, CTRL_N). In a second state, the first SPDT switch S1 can be connected to the second voltage V2 and the second SPDT switch S2 can be connected to the first voltage V1 to apply a forward bias to the diode D1.

FIG. 3 illustrates a current-limiting diode CLD1 in the bias line of the PIN diode D1. The bias line can further include a bypass diode BD1 for bypassing the current-limiting elements in order to provide a reverse bias to the PIN diode D1 as needed. In one embodiment, a current-limiting element can be capacitively bypassed to charge the diode capacitance for reverse bias.

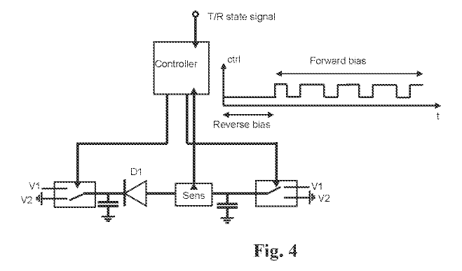

FIG. 4 is an illustration of the detuning mechanism wherein the control signal is delivered to the diode driver by a controller according to one embodiment. In one embodiment, the controller can include the state detection circuitry. In one embodiment, the controller can include pulse or edge detection circuitry as described herein. In one embodiment, the controller can receive a state signal indicating the state of the MRI scanner (e.g., transmission state, receiving state) as an input. The state signal can include, for example, sensor data from the transmission coil or a signal transmitted from an antenna of the transmission coil. The controller can generate and output a control signal to the diode driver(s) based on the state signal. The control signal can include a pulse train (e.g., PWM signal) indicating forward bias. In the example of FIG. 4, the diode drivers can include the first SPDT switch S1 and second SPDT switch S2. In one embodiment, diode drivers can include pulse detection circuitry to switch to a forward bias state when the control signal includes the pulses illustrated in FIG. 4.

In one embodiment, the receiver coil can include monitoring circuitry (sensing circuitry) for monitoring operation of elements in the detuning mechanism, amplifier mechanism, etc. The sensing circuitry can include current sensing circuitry and/or voltage sensing circuitry. For example, current sensing elements can include buffers and integrated chip modules. The current draw of the transmission line can indicate whether the components receiving current from the transmission line are operating properly. For example, the transmission line can deliver a biasing voltage to the diode of the detuning mechanism. The current draw of the diode can change depending on the bias (forward or reverse) being applied to the diode. Current sensing circuitry can determine the bias state of the diode based on the current draw.

In one embodiment, the monitoring circuitry can measure voltage and/or current across circuit elements in the receiver coil and can compare measured voltage and/or current values to expected values. The expected values can include values indicating functional operation or values indicating failure of a circuit element or branch in the receiver coil circuitry. In one embodiment, the measured voltage and/or current values can be used to control the operation of the MRI system. For example, the MRI scanning process can be halted when the voltage and/or current values indicate that an element of the receiver coil (e.g., the detuning mechanism) has failed. As illustrated in FIG. 4, the controller can receive feedback from sensing circuitry (Sens) in line with the diode D1. The sensor readings can be used to confirm the bias state of the diode D1. In one embodiment, the controller can modify the control signal based on the sensor readings.

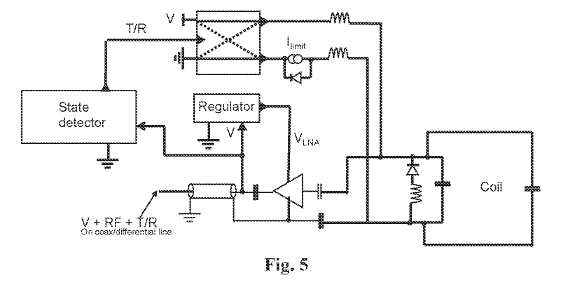

FIG. 5 is an illustration of a receiver coil design according to one embodiment. The receiver channel can include a voltage regulator configured to generate a stable voltage V_{LNA} (amplifier bias voltage supply) to bias the preamplifier (e.g., an LNA). In one embodiment, the voltage regulator can be a linear regulator, such as a low-dropout (LDO) regulator. The first voltage can be input to the voltage regulator from the transmission line. The voltage regulator can provide a stable voltage to the preamplifier so that the preamplifier has a short recovery time when switching between transmission and receiving states. Stabilizing the bias voltage can also prevent transient behavior such as thermal transients. In one embodiment, the preamplifier does not need to be gain-stable or have a short bias-switching transient time because the voltage regulator supplies a stable voltage. In one embodiment, the receiver coil can include an active current source configured to inject a current to the preamplifier in order to stabilize the preamplifier.

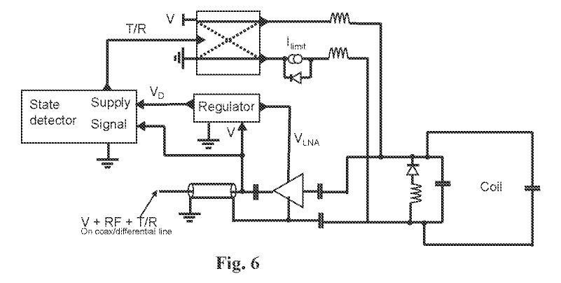

FIG. 6 is an illustration of a receiver coil design according to one embodiment. In one embodiment, the voltage regulator can further supply a stable voltage V_{D} to the state detection circuitry based on the first voltage. The voltage V_{D} can be the same as or different from the voltage V_{LNA.}

In one embodiment, one or more components of the receiver coil design can be integrated into an application-specific integrated circuit (ASIC). For example, the state detection circuitry, diode driver, voltage regulator, etc. can be implemented in one or more integrated circuits. In one embodiment, more than one antenna or coil can share the circuitry components described herein. For example, the detuning circuitry can be used to detune a number of coils in a synchronized or unsynchronized manner.

In one embodiment, the voltage regulator can generate a stable voltage and output the stable voltage to a terminal of the DPDT switch. For example, the first voltage of the DPDT switch can be output by the voltage regulator. In this manner, the PIN diode can be biased with a stable voltage to ensure the bias state. In one embodiment, the voltage regulator can include a voltage converter, e.g., a switch mode power supply such as a buck-boost converter. The voltage converter can be used to step an input voltage (e.g., the first voltage) up or down to generate V_{D} or V_{LNA.}

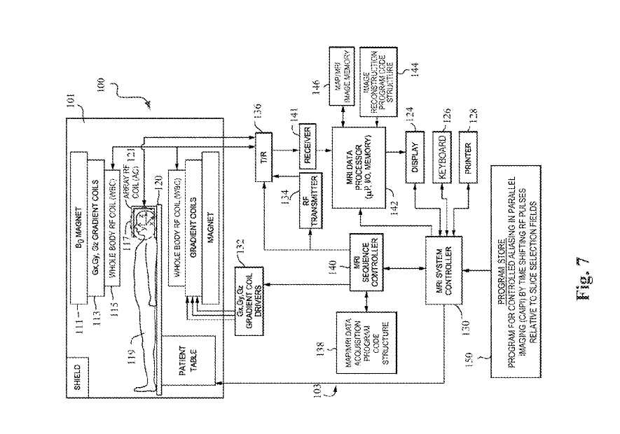

Referring now to FIG. 7, a non-limiting example of a magnetic resonance imaging (MRI) system 100 is shown. The MRI system 100 depicted in FIG. 7 includes a gantry 101 (shown in a schematic cross-section) and various related system components 103 interfaced therewith. At least the gantry 101 is typically located in a shielded room. The MRI system geometry depicted in FIG. 7 includes a substantially coaxial cylindrical arrangement of the static field B0 magnet 111, Gx, Gy, and Gz gradient coil set 113, and a large whole-body RF coil (WBC) assembly 115. Along a horizontal axis of this cylindrical array of elements is an imaging volume 117 shown as substantially encompassing the head of a patient 119 supported by a patient table 120.

One or more smaller array RF coils 121 can be more closely coupled to the patient’s head (referred to herein, for example, as “imaging object” or “object”) in imaging volume 117. As those in the art will appreciate, compared to the WBC (whole-body coil), relatively small coils and/or arrays, such as surface coils or the like, are often customized for particular body parts (e.g., arms, shoulders, elbows, wrists, knees, legs, chest, spine, etc.). Such smaller RF coils are referred to herein as array coils (AC) or phased-array coils (PAC). These can include at least one coil configured to transmit RF signals into the imaging volume, and a plurality of receiver coils configured to receive RF signals from an object, such as the patient’s head, in the imaging volume.

The MRI system 100 includes an MRI system controller 130 that has input/output ports connected to a display 124, a keyboard 126, and a printer 128. As will be appreciated, the display 124 can be of the touch-screen variety so that it provides control inputs as well. A mouse or other I/O device(s) can also be provided.

The MRI system controller 130 interfaces with an MRI sequence controller 140, which, in turn, controls the Gx, Gy, and Gz gradient coil drivers 132, as well as the RF transmitter 134, and the transmit/receive switch 136 (if the same RF coil is used for both transmission and reception). The RF transmitter 134 may be composed of two or more transmitter channels for driving two or more RF transmit coils or ports on coils, as is used for RF shimming. The MRI sequence controller 140 includes suitable program code structure 138 for implementing MRI imaging (also known as nuclear magnetic resonance, or NMR, imaging) techniques including B1 field shimming. MRI sequence controller 140 can be configured for MR imaging with or without parallel imaging. Moreover, the MRI sequence controller 140 can facilitate one or more preparation scan (pre-scan) sequences, and a scan sequence to obtain a main scan magnetic resonance (MR) image (referred to as a diagnostic image). MR data from pre-scans can be used, for example, to determine shimming parameters for RF coils 115 and/or 121.

The MRI system components 103 include an RF receiver 141 providing input to data processor 142 so as to create processed image data, which is sent to display 124. The MRI data processor 142 is also configured to access previously generated MR data, images, navigator data, system configuration parameters 146, and/or program code structures 144 and 150.

In one embodiment, the MRI data processor 142 includes processing circuitry. The processing circuitry can include devices such as an application-specific integrated circuit (ASIC), configurable logic devices (e.g., simple programmable logic devices (SPLDs), complex programmable logic devices (CPLDs), and field programmable gate arrays (FPGAs), and other circuit components that are arranged to perform the functions recited in the present disclosure, such as described with respect to FIGS. 1-6.

The processor 142 executes one or more sequences of one or more instructions contained in the program code structures 144 and 150. Alternatively, the instructions can be read from another computer-readable medium, such as a hard disk or a removable media drive. One or more processors in a multi-processing arrangement can also be employed to execute the sequences of instructions contained in the program code structures 144 and 150. In alternative embodiments, hard-wired circuitry can be used in place of or in combination with software instructions. Thus, the disclosed embodiments are not limited to any specific combination of hardware circuitry and software. For example, the program code structure 150 can store instructions that when executed perform the method 200.

Additionally, the term “computer-readable medium” as used herein refers to any non-transitory medium that participates in providing instructions to the processor 142 for execution. A computer readable medium can take many forms, including but not limited to, non-volatile media or volatile media. Non-volatile media includes, for example, optical, magnetic disks, and magneto-optical disks, or a removable media drive. Volatile media includes dynamic memory.

Also illustrated in FIG. 7 is a generalized depiction of an MRI system program storage (memory) 150, where stored program code structures such as instructions to perform the method 200 are stored in non-transitory computer-readable storage media accessible to the various data processing components of the MRI system 100. As those in the art will appreciate, the program store 150 can be segmented and directly connected, at least in part, to different ones of the system 103 processing computers having most immediate need for such stored program code structures in their normal operation (i.e., rather than being commonly stored and connected directly to the MRI system controller 130).

Additionally, the MRI system 100 as depicted in FIG. 7 can be utilized to practice exemplary embodiments described herein. The system components can be divided into different logical collections of “boxes” and typically comprise numerous digital signal processors (DSP), microprocessors and special purpose processing circuits (e.g., for fast A/D conversions, fast Fourier transforming, array processing, etc.). Each of those processors is typically a clocked “state machine” wherein the physical data processing circuits progress from one physical state to another upon the occurrence of each clock cycle (or predetermined number of clock cycles).

Furthermore, not only does the physical state of the processing circuits (e.g., CPUs, registers, buffers, arithmetic units, etc.) progressively change from one clock cycle to another during the course of operation, the physical state of associated data storage media (e.g., bit storage sites in magnetic storage media) is transformed from one state to another during operation of such a system. For example, at the conclusion of an image reconstruction process and/or sometimes an image reconstruction map (e.g., coil sensitivity map, unfolding map, ghosting map, a distortion map etc.) generation process, an array of computer-readable accessible data value storage sites in physical storage media will be transformed from some prior state to a new state wherein the physical states at the physical sites of such an array vary between minimum and maximum values to represent real world physical events and conditions. As those in the art will appreciate, such arrays of stored data values represent and also constitute a physical structure, as does a particular structure of computer control program codes that, when sequentially loaded into instruction registers and executed by one or more CPUs of the MRI system 100, causes a particular sequence of operational states to occur and be transitioned through within the MRI system 100.

Numerous modifications and variations of the present invention are possible in light of the above teachings. It is therefore to be understood that within the scope of the appended claims, the invention may be practiced otherwise than as specifically described herein.

1. An apparatus for decoupling magnetic resonance imaging (MRI) coils, comprising:
an amplifier configured to amplify a radiofrequency (RF) signal received from an RF coil of an MRI scanner;
state detection circuitry configured to output a control signal based on a state of the RF coil;
a unipolar diode driver configured to receive the control signal and output a bias voltage based on the received control signal;
a voltage regulator configured to output an amplifier bias voltage to the amplifier; and
a transmission line configured to transmit the amplified RF signal from the amplifier, the control signal to the unipolar diode driver, and a bias voltage supply, wherein
the outputted amplifier bias voltage from the voltage regulator is applied to the amplifier and the outputted bias voltage from the unipolar diode driver is applied to a detuning switch of the RF coil that is connected to the amplifier, and
the amplifier, the state detection circuitry, the unipolar diode driver, and the voltage regulator are on a first end of the transmission line.

2. The apparatus of claim 1, wherein the state detection circuitry is coupled to an output of the amplifier, or to a pick-up circuit coupled to the RF coil.

3. The apparatus of claim 1, wherein the state detection circuitry includes a Schmitt trigger, a monostable circuit, or a flip-flop circuit.

4. The apparatus of claim 1, wherein the state detection circuitry includes a pulse detector or an edge detector.

5. The apparatus of claim 1, wherein the unipolar diode driver includes a double-pole double-throw (DPDT) switch.

6. The apparatus of claim 1, wherein the unipolar diode driver includes an H-bridge.

7. The apparatus of claim 1, wherein the unipolar diode driver includes a switched-mode power supply.

8. The apparatus of claim 1, wherein the unipolar diode driver is coupled to a direct current (DC) to DC voltage converter.

9. The apparatus of claim 1, wherein the detuning switch is a PIN diode coupled to a parallel LC circuit.

10. The apparatus of claim 1, wherein the unipolar diode driver has three output states and is configured to apply a reverse bias, a low-current forward bias, or a high-current forward bias to the detuning switch.

11. The apparatus of claim 10, wherein the unipolar diode driver is coupled to or contains an active current source.

12. The apparatus of claim 1, further comprising current sensing circuitry configured to determine a current in the transmission line, compare the determined current to a current threshold, and output the control signal to the unipolar diode driver based on the comparison of the determined current to the current threshold.

13. The apparatus of claim 1, further comprising current sensing circuitry configured to determine a bias current in the PIN diode, compare the determined bias current to a current threshold, and output the control signal to the unipolar diode driver based on the comparison of the determined current to the current threshold.

14. An apparatus for decoupling magnetic resonance imaging (MRI) coils, comprising:
an amplifier configured to amplify a radiofrequency (RF) signal received from an RF coil of an MRI scanner;
a unipolar diode driver configured to receive a control signal and output a bias voltage based on the received control signal;
a voltage regulator configured to output an amplifier bias voltage to the amplifier; and
a transmission line configured to transmit the amplified RF signal from the amplifier, the control signal to the unipolar diode driver, and a bias voltage supply, wherein
the outputted amplifier bias voltage from the voltage regulator is applied to the amplifier and the outputted bias voltage from the unipolar diode driver is applied to a detuning switch of the RF coil that is connected to the amplifier, and
the amplifier, the unipolar diode driver, and the voltage regulator are on a first end of the transmission line.

15. The apparatus of claim 14, wherein the state detection circuitry includes a pulse detector or an edge detector.

16. The apparatus of claim 14, wherein the state detection circuitry includes a double-pole double-throw (DPDT) switch.

17. The apparatus of claim 14, wherein the unipolar diode driver has three output states and is configured to apply a reverse bias, a low-current forward bias, or a high-current forward bias to the detuning switch.

18. The apparatus of claim 14, wherein the detuning switch is a PIN diode coupled to a parallel LC circuit.

19. A method of decoupling magnetic resonance imaging (MRI) coils, comprising:
determining a state of a radiofrequency (RF) coil of an MRI scanner;
generating a control signal based on the determined state of the RF coil;
transmitting the generated control signal to a unipolar diode driver;
outputting a stabilized amplifier bias voltage from a voltage regulator to an amplifier configured to amplify an RF signal received from the RF coil;
outputting a bias voltage from the unipolar diode driver based on the generated control signal; and
applying the outputted stabilized amplifier bias voltage from the voltage regulator to the amplifier and the outputted bias voltage from the unipolar diode driver to a detuning switch of the RF coil that is connected to the amplifier, wherein
the detuning switch of the RF coil is a PIN diode coupled to a parallel LC circuit, and
the amplified RF signal, the control signal, and a bias voltage supply are transmitted by a single transmission line.

20. The method of claim 19, wherein the outputting the bias voltage includes outputting a reverse bias voltage, a high-current forward bias voltage, or a low-current forward bias voltage using the unipolar diode driver.
